(19) United States
(12) Patent Application Publication
(10) Pub. No.: US 2006/0017352 A1
(43) Pub. Date: Jan. 26, 2006

(54) Thin device and method of fabrication

(76) Inventor: Aram Tanielian, Rancho Palos Verdes, CA (US)

Correspondence Address: GENE SCOTT; PATENT LAW & VENTURE GROUP, 3140 RED HILL AVENUE, SUITE 150, COSTA MESA, CA, 92626-3440, US

(21) Appl. No.: 10/895,767

(22) Filed: Jul. 20, 2004

(51) Int. Cl. H01L 41/08

(52) U.S. Cl. 310/324

(57) ABSTRACT

A method of fabricating air-bridge type FBAR devices provides for a piezoelectric material sandwiched between two electrodes with an air/crystal interface on each electrode to trap sound waves within the film structure. Copper is used as a sacrificial material deposited in cavities in the substrate. Following deposition of the electrodes and piezoelectric material, the copper is etched away leaving the bottom electrode suspended over a cavity void.

### BACKGROUND OF THE INVENTION

### INCORPORATION BY REFERENCE

Applicant(s) hereby incorporate herein by reference, any and all U.S. patents and U.S. patent applications cited or referred to in this application.

### FIELD OF THE INVENTION

This invention relates generally to thin film microdevices and method of manufacture, and more particularly to a thin film bulk acoustic resonator device having advantages in fabrication and operation.

### DESCRIPTION OF RELATED ART

Acoustic resonators are used as filters for electronic circuits and there has been a continuing effort to provide reliable, inexpensive and compact devices. The basic structure consists of a sputtered piezoelectric film sandwiched between metal electrodes. The device is fabricated on an insulating substrate with bonding pads for electrode and ground plane connections. The devices are then tested and separated. The good devices are mounted and bonded into a package. The following art defines the present state of this field.

Ruby et al, U.S., 2003/0098631 describes an array of acoustic resonators, the resonant frequencies of the resonators are adjusted and stabilized in order to achieve target frequency responses for the array. The method of adjusting is achieved by intentionally inducing oxidation at an elevated temperature. Thermal oxidation grows a molybdenum oxide layer on the surface of the top electrode of an electrode-piezoelectric stack, thereby increasing the relative thickness of the electrode layer to the piezoelectric layer. In one embodiment, the resonant frequency of an FBAR is adjusted downwardly as the top electrode layer increases relative to the piezoelectric layer. In another embodiment, the method of stabilizing is achieved by intentionally inducing oxidation at an elevated temperature.

Ruby et al, U.S. Pat. No. 6,060,818, describes an acoustical resonator and a method for making the same. A resonator according to the present invention includes a layer of piezoelectric material sandwiched between first and second electrodes. The first electrode includes a conducting sheet having a RMS variation in height of less than 2 .mu.m. The resonator bridges a cavity in a substrate on which the resonator is constructed. The resonator is constructed by creating a cavity in the substrate and filling the same with a sacrificial material that can be rapidly removed from the cavity after the deposition of the various layers making up the resonator. The surface of the filled cavity is polished to provide a RMS variation in height of less than 0.5 .mu.m. The first electrode is deposited on the polished surface to a thickness that assures that the RMS variation in height of the metallic layer is less than 2 .mu.m. The piezoelectric layer is deposited on the first electrode and the second electrode is then deposited on the piezoelectric layer. The sacrificial material is then removed from the cavity by opening vias into the cavity and removing the material through the vias. The preferred sacrificial material is phophor-silica-glass.

Ruby, U.S. Pat. No. 6,377,137 B1, describes a plurality of acoustic resonators manufactured in a batch process by forming cavities in a substrate and filling the cavities with a sacrificial layer. An FBAR membrane comprising a bottom electrode, a piezoelectric layer, and a top electrode is formed over each cavity and the sacrificial layer. The substrate is then thinned and the substrate is separated into a plurality of dice using a scribe and break process. The sacrificial layer is then removed and the FBAR filter is mounted in a package with thermal vias being thermal communication with underside of the FBAR filter. The production method improves thermal properties by increasing the efficiency of heat dissipation from the FBAR filter. In addition, electromagnetic interference is decreased by reducing the distance between a primary current flowing over the surface of the FBAR filter and an image current flowing in a ground plane beneath the FBAR filter.

Ruby, U.S. Pat. No. 6,384,697 B1, describes a filter formed of acoustic resonators, where each resonator has its own cavity and a bottom electrode that spans the entirety of the cavity, so that the bottom electrode has an unsupported interior region surrounded by supported peripheral regions. In the preferred embodiment, the cavity is formed by etching a depression into the substrate, filling the depression with a sacrificial material, depositing the piezoelectric and electrode layers that define an FBAR or SBAR, and then removing the sacrificial material from the depression. Also in the preferred embodiment, the sacrificial material is removed via release holes that are limited to the periphery of the depression. Preferably, the bottom electrode is the only electrode that spans the cavity, thereby limiting the formation of parasitic FBARs or SBARs. In one embodiment, the bottom electrode includes a serpentine edge that leaves a portion of one side of the cavity free of overlap by the bottom electrode, so that a top electrode may overlap this portion. Thus, the top and bottom electrodes can overlap the same side without sandwiching the piezoelectric layer outside of the unsupported interior region.

Ruby et, al, U.S. Pat. No. 6,424,237 B1, describes a bulk acoustic resonator having a high quality factor is formed on a substrate having a depression formed in a top surface of the substrate. The resonator includes a first electrode, a piezoelectric material and a second electrode. The first electrode is disposed on the top surface of the substrate and extends beyond the edges of the depression by a first distance to define a first region therebetween. The piezoelectric material is disposed on the top surface of the substrate and over the first electrode, and the second electrode is disposed on the piezoelectric material. The second electrode includes a portion that is located above the depression. The portion of the second electrode that is located over the depression has at least one edge that is offset from a corresponding edge of the depression by a second distance to define a second region therebetween. The first and second regions have different impedances, as a result of the different materials located in the two regions. In addition, the first and second distances are approximately equal to a quarter-wavelength of a sound wave traveling laterally across the respective region, such that reflections off of the edges of the regions constructively interfere to maximize the reflectivity of the resonator.

Ella et al, U.S. Pat. No. 6,441,702 B1, describes a method and system for tuning a bulk acoustic wave device at the wafer level by adjusting the thickness of the device. In particular, the thickness of the device has a non-uniformity profile across the device surface. A mask having a thickness non-uniformity profile based partly on the thickness non-uniformity profile of the device surface is provided on the device surface for etching. A dry etching method is used to remove part of the mask to expose the underlying device surface and further removed the exposed device surface until the thickness non-uniformity of the device surface falls within tolerance of the device.

Ella et al, U.S. Pat. No. 6,456,173 B1, describes a method and system for tuning a bulk acoustic wave device at the wafer level by adjusting the device thickness. In particular, the device thickness has a non-uniformity profile across the device surface. A mask with an aperture is placed over the device surface and a particle beam is applied over the mask to allow part of the particle beam to make contact with the device surface at a localized area beneath the aperture. The particles that pass through the aperture are deposited on the device surface to add material on the device surface, thereby increasing the surface thickness to correct for thickness non-uniformity. Alternatively, the particles that pass through the aperture remove part of the device surface in an etching process, thereby reducing the surface thickness. Prior to thickness adjustment, a frequency measurement device or thickness measurement device is used to map the device surface for obtaining the non-uniformity profile.

Aigner et al, U.S. Pat. No. 6,542,054 B2, describes an acoustic mirror which is formed of at least one first insulating layer, a first metal layer disposed thereon, a second insulating layer disposed thereon and a second metal layer disposed thereon. An auxiliary layer is produced on the first insulating layer whereby a recess extending as far as the first insulating layer is created therein. The first metal layer is substantially deposited and removed by chemical/mechanical polishing until the parts of the first metal layer disposed outside the recess are no longer present. The second metal layer is also produced in a recess with the aid of chemical/mechanical polishing. More than two insulating layers and two metal layers can be provided. The first metal layer and the second metal layer can be produced in the same recess.

Ruby et al, U.S. Pat. No. 6,469,597 B2, describes a method for fabricating a resonator, and in particular, a thin film bulk acoustic resonator (FBAR), and a resonator embodying the method are disclosed. An FBAR is fabricated on a substrate by introducing a mass loading electrode to a bottom electrode layer. For a substrate having multiple resonators, mass loading bottom electrode is introduced for only selected resonator to provide resonators having different resonance frequencies on the same substrate.

Kaitila et al, U.S. Pat. No. 6,480,074 B1, describes a method and system for tuning a bulk acoustic wave device at wafer level by reducing the thickness non-uniformity of the topmost surface of the device using a chemical vapor deposition process. A light beam is used to enhance the deposition of material on the topmost surface at one local location at a time. Alternatively, an electrode is used to produce plasma for locally enhancing the vapor deposition process. A moving mechanism is used to move the light beam or the electrode to different locations for reducing the thickness non-uniformity until the resonance frequency of the device falls within specification.

Larson, III et al, U.S. Pat. No. 6,483,229 B2, describes a method for fabricating a resonator, and in particular, a thin film bulk acoustic resonator (FBAR), and a resonator embodying the method are disclosed. An FBAR is fabricated on a substrate by mass loading piezoelectric (PZ) layer between two electrodes. For a substrate having multiple resonators, only selected resonator is mass loaded to provide resonators having different resonance frequencies on the same substrate.

Barber et al, U.S. Pat. No. 6,486,751 B1, describes improved bandwidths and oscillation uniformity obtained through a rod type BAW TFR structure formed over a semiconductor support. The resonator includes a first and a second electrode and a plurality of distinct elemental piezoelectric structures between the electrodes. Each of the piezoelectric structures has a length, a width and a height, the height being the distance between the electrodes. The height of the piezoelectric structures is at least equal to or more than one of the length or the width, or both. Such resonator is made by forming on a common bottom a plurality of distinct piezoelectric structures each having a length, a width and a height, wherein the height is formed at least equal to the width or the length of the piezoelectric structure, and forming a common top electrode there over.

Ruby et al, U.S. Pat. No. 6,472,954 B1, describes an array of acoustic resonators, wherein the effective coupling coefficient of first and second filters are individually tailored in order to achieve desired frequency responses. In a duplexer embodiment, the effective coupling coefficient of a transmit band-pass filter is lower than the effective coupling coefficient of a receive band-pass filter of the same duplexer. In one embodiment, the tailoring of the coefficients is achieved by varying the ratio of the thickness of a piezoelectric layer to the total thickness of electrode layers. For example, the total thickness of the electrode layers of the transmit filter may be in the range of 1.2 to 2.8 times the total thickness of the electrode layers of the receive filter. In another embodiment, the coefficient tailoring is achieved by forming a capacitor in parallel with an acoustic resonator within the filter for which the effective coupling coefficient is to be degraded. Preferably, the capacitor is formed of the same materials used to fabricate a film bulk acoustic resonator (FBAR). The capacitor may be mass loaded to change its frequency by depositing a metal layer on the capacitor. Alternatively, the mass loading may be provided by forming the capacitor directly on a substrate.

Larson, III et al, U.S. Pat. No. 6,566,979 B2, describes a method for fabricating a resonator, and in particular, a thin film bulk acoustic resonator (FBAR), and a resonator embodying the method are disclosed. A resonator is fabricated on a substrate, and its top electrode 56 is oxidized to form a oxide layer 58. For a substrate having multiple resonators, the top electrode 56 of only selected resonator is oxidized to provide resonators having different resonance frequencies on the same substrate.

Ruby et al, U.S. Pat. No. 6,617,249 B2, describes a method for fabricating a resonator, and in particular, a thin film bulk acoustic resonator (FBAR), and a resonator embodying the method are disclosed. An FBAR is fabricated on a substrate by introducing a mass loading top electrode layer. For a substrate having multiple resonators, the top mass loading electrode layer is introduced for only selected resonator to provide resonators having different resonance frequencies on the same substrate.

Barber et al, U.S. Pat. No. 6,657,517 B2, describes how differing metallic electrodes having the same or differing thickness are formed at different locations on a support structure and/or on a single thickness film of piezoelectric material in order to form a multiple frequency resonator device having greatly separated acoustic resonance frequencies. A plurality of multiple frequency resonators can be combined to form a blank of frequency selective devices in order to handle the many different RF bands, at widely varying frequencies, that wireless communication technologies demand today.

Wang, et al, U.S. Pat. No. 6,662,419 B2, describes a method for forming film bulk acoustic resonator devices including depositing a first portion of a first electrode, and a piezoelectric layer onto a substrate. The method includes removing a portion of the substrate under the piezoelectric layer and under the portion of the first electrode, and depositing a second portion of the first electrode onto the piezoelectric film layer and onto the first portion of the first electrode.

Itasaka, U.S. Pat. No. 6,711,792 B2, describes a piezoelectric resonator is constructed to be vibrated in a square type vibration mode and to minimize the variations in the resonant frequency caused by the manufacturing process. The resonator includes a piezoelectric substrate having a pair of main surfaces, electrodes disposed on the pair of main surfaces and grooves provided on one of the main surfaces of the piezoelectric substrate. The grooves divide at least one of the electrodes into a plurality of divided electrodes. One of the plurality of divided electrodes defines an input/output electrode. A maximum distance between the outer edges of two of the grooves disposed opposite to each other across the input/output electrode is about 0.5 to about 0.55 times the length of one side edge of the piezoelectric substrate.

Our prior art search with abstracts described above teaches: a cavity spanning bottom electrode of a substrate-mounted bulk wave acoustic resonator, an acoustic resonator filter with reduced electromagnetic influence due to die substrate thickness, a method for making thin film bulk acoustic resonators with different frequencies on a single substrate and apparatus embodying the method, a SBAR structure and nmthod of fabrication of SBAR and fbar film processing techniques for the manufacturing of SBAR and FBAR filters, method of fabricating thin film bulk acousitic resonator and FBAR structure embodying the method, a bulk acoustic resonator perimeter reflection system, a method of mass loading of thin film bulk acoustic resonators and creating resonators of different frequencies and apparatus embodying the method, controlled effective coupling coefficients for film bulk acoustic resonators, method for adjusting and stabilizing the frequency of an acoustic resonator, a method and system for wafer level tuning of bulk acoustic wave resonators and filters, a method and system for wafer-level tuning of bulk acoustic wave resonators and filters, an acoustic mirror and method for producing the acoustic mirror, a method and system for wafer-level tuning of bulk acoustic wave resonators and filters by reducing thickness non-uniformity, an increased bandwidth thin film resonator having a columnar structure, a method of providing differential frequency adjusts in a thin film bulk acoustic resonator filter and apparatus embodying the method, a method of providing differential frequency adjusts in a thin film bulk acoustic resonator filter and apparatus embodiying the method, and a method for fabricating film bulk acoustic resonators to achieve high-Q and low loss. However, the present state of the art and the prior art fail to teach INSERT. The present invention fulfills these needs and provides further related advantages as described in the following summary.

### SUMMARY OF THE INVENTION

Acoustic resonators, i.e, FBAR and similar devices use certain crystal structures. Such structures are also useful in MEM devices (micro-electromechanical), transducers and sensors. In order to provide an air/crystal interface on the bottom electrode, an air bridge is created before deposition of the electrode material. This is done by creating a well in the substrate and filling it with a sacrificial material which can be easily removed following deposition of the top electrode. This material must not be rough because the piezoelectric material must be well-collimated for it to act as an acoustic resonator. Prior methods have used phosphor-silica-glass (PSG) as the sacrificial layer, but it requires polishing and special cleanup methods in order to obtain the required smooth surface. This operation is tedious and time consuming. After processing, the devices are separated into individual chips.

This object of this invention is to provide a smooth sacrificial layer for fabrication of the device without the necessity of additional lapping and cleaning. The instant sacrificial layer is easily etched away and does not require extensive cleanup. The finished chip will have enhanced performance because of the ground shield surrounding the electrodes and the elimination of bond wire inductance and parasitic capacitance.

The present invention teaches certain benefits in construction and use which give rise to the following objectives.

A primary objective of the present invention is to provide an device and method of making the device that yields advantages not taught by the prior art.

Another objective is to provide such an invention wherein fabrication is simplified and a more reliable device is produced.

A further objective is to provide such an invention capable of producing FBAR devices with improved performance.

Other features and advantages of the embodiments of the present invention will become apparent from the following more detailed description, taken in conjunction with the accompanying drawings, which illustrate, by way of example, the principles of at least one of the possible embodiments of the invention.

### BRIEF DESCRIPTION OF THE DRAWINGS

The accompanying drawings illustrate at least one of the best mode embodiments of the present invention. In such drawings:

FIG. 1 is a perspective view of a substrate with an oxide layer formed on it and a well formed in the oxide layer;

FIG. 2 is a perspective view of the oxide layer with further layers formed over the oxide and patterned prior to placement of bonding bumps;

FIG. 3 is a vertical cross sectional view through the near finished device showing constructional details; and

FIG. 4 is perspective view of the finished device.

### DETAILED DESCRIPTION OF THE INVENTION

The above described drawing figures illustrate the present invention in at least one of its preferred, best mode embodiments, which is further defined in detail in the following description. Those having ordinary skill in the art may be able to make alterations and modifications in the present invention without departing from its spirit and scope. Therefore, it must be understood that the illustrated embodiments have been set forth only for the purposes of example and that they should not be taken as limiting the invention as defined in the following.

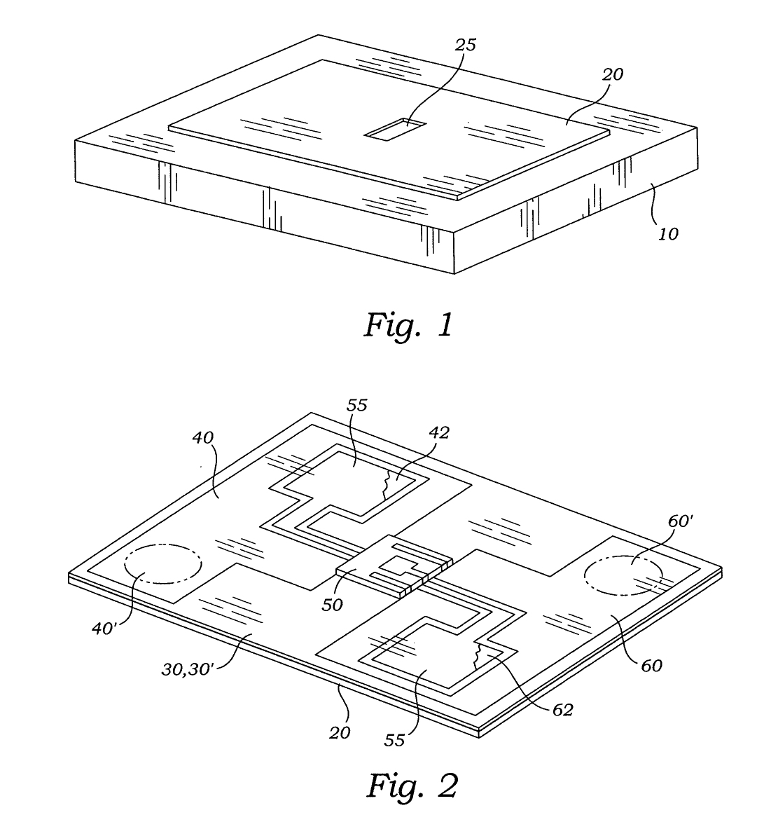

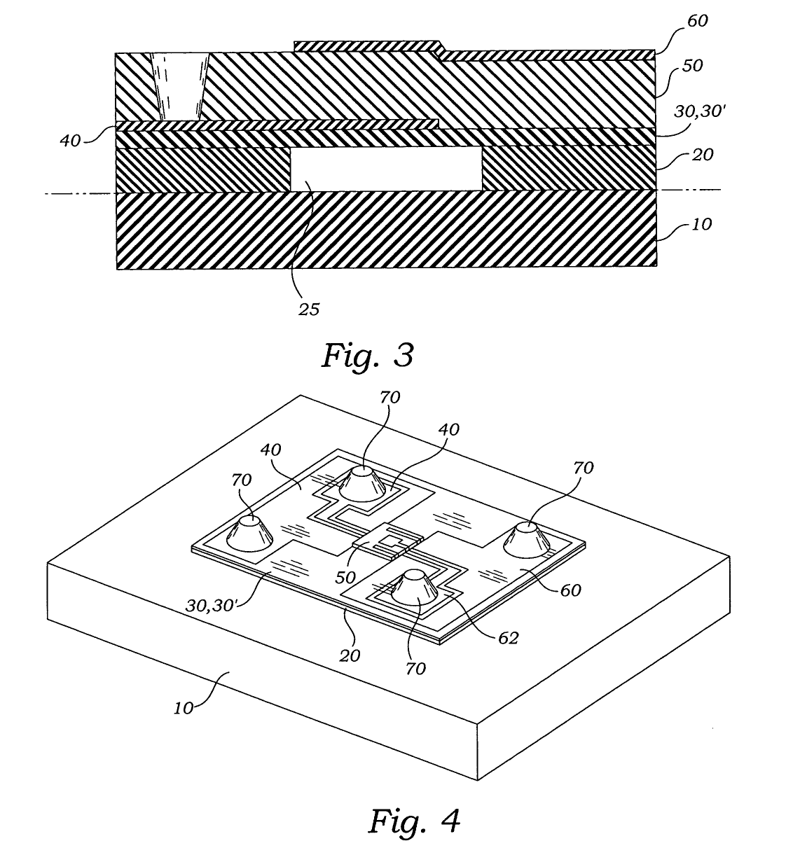

In one embodiment of the present invention, as shown in FIG. 1, a thermal oxide layer 20 of approximately 1.5 μm in thickness is grown on a silicon wafer substrate 10 having an exposed surface with a smoothness of about 0.3 μm RMS. The oxide layer 20 is patterned with a photoresist (not shown) and etched using standard photolithographic techniques in order to create a square or rectangular well 25 through the oxide layer for each device that is being fabricated on the substrate 10. In the figures, fabrication of one device is shown, however, typically many devices are fabricated simultaneously in the same manner as defined herein. In this description the fabrication of a single device is described, but it should be understood that plural devices are fabricated in the same manner at the same time. A 1.5 μm thick layer of sacrificial copper metal 28 is deposited onto the exposed surfaces including the photoresist and into the wells 25. The copper thickness is equal to that of the oxide layer 20 so that the well 25 is filled to the level of the exposed surface of the oxide layer 20. The photoresist is now etched away taking with it the copper layer 28 which is on top of it, but not the copper 28 within the well 25. This leaves a planar surface of oxide 10 with a copper area defining the location of the well 25. The exposed surfaces of the oxide layer 20 and the copper layer 28 lie in a common plane which is 1.5 μm above the wafer surface. This technique is an improvement over the prior art which teaches that, at this point in the fabrication, the exposed surface must be planarized by polishing with a slurry which requires subsequent critical cleaning steps. In the present method such cleaning is avoided. There are also no voids in the oxide 20 or the copper 28 because the same mask is used to pattern both layers. In the prior art, where the sacrificial metal is etched away, instead of being lifted, the masked area is subject to misalignment.

Next, thin layers of between 0.4 and 0.8 μm of SiO₂, an easily etched dielectric material, and 0.03 μm of Al₂O₃ (30′), or any alternative material that promotes columnar growth of a subsequent piezoelectric layer, are deposited on the exposed surfaces of the oxide layer 20 and the copper sacrificial metal layer 28. The Al₂O₃ may alternately be SiON, calcium fluoride, tantalum pentoxide or other insulators that deposit smoothly, achieve a state of low stress and are easily patterned, i.e., etched.

Following this, a bottom ground shield 40 and bottom electrode metal layer 42 of between 0.3 and 0.8 μm thickness is patterned and deposited using one of molybdenum, tungsten, platinum, tantalum or aluminum as shown in FIG. 2. Potentially, other metals may be used for this function, but molybdenum is the preferred choice. A layer of gold 55 is then deposited over the electrode metal 42 and a portion 40′ of the bottom ground shield, as shown in FIG. 2.

Over the bottom electrode 40 at the center of the device, as shown in FIG. 2, a 0.6 to 2.0 μm thick layer of AlN piezoelectric film 50 is deposited, preferably by sputtering, and alternatively, the film 50 may be ZnO or Li-niobate or related materials. The SiO₂ and Al₂O₃ layers 30, 30′ enhance the <002> orientation of the AlN film 50 and also protects the sacrificial copper 28 during subsequent processing.

Next, a top ground shield 60 and a top electrode metal layer 62, identical to the bottom electrode layer in thickness and of the same material, is patterned and deposited over the AlN layer 50, again as shown in FIG. 2. A further layer of gold 55 is then patterned and deposited over the electrode metal 62 and a portion of the top ground shield 60, as shown in FIG. 2. The gold layers 55 assure good electrical contact to subsequent bonding material 70, as shown in FIG. 4. It is noted that the electrode metal layers 42 and 62 are patterned with separation from the bottom and top ground shields 40 and 60 respectively.

The portions of the bottom and top electrode metal layers 42 and 62 respectively, which lie in opposition, define an active area between them within the piezoelectric film 50.

After the top ground shield 60 is patterned and etched, the piezoelectric layer 50 is masked to expose the contact areas of the bottom electrode 42, which forms a ground plane, and also, the copper 28 in the well 25. The piezoelectric film 50 is then removed from these areas.

The SiO₂ and Al₂O₃ layers 30, 30′ covering the exposed copper 28 is now removed and the substrate 10 is placed in a copper etch solution to vacate the well 25 without attacking the electrode metals 42, 62 or the piezoelectric film 50. Extensive cleaning is not required in this process.

The enablements described in detail above are considered novel over the prior art of record and are considered critical to the operation of at least one aspect of one best mode embodiment of the instant invention and to the achievement of the above described objectives. The words used in this specification to describe the instant embodiments are to be understood not only in the sense of their commonly defined meanings, but to include by special definition in this specification: structure, material or acts beyond the scope of the commonly defined meanings. Thus if an element can be understood in the context of this specification as including more than one meaning, then its use must be understood as being generic to all possible meanings supported by the specification and by the word or words describing the element.

The definitions of the words or elements of the embodiments of the herein described invention and its related embodiments not described are, therefore, defined in this specification to include not only the combination of elements which are literally set forth, but all equivalent structure, material or acts for performing substantially the same function in substantially the same way to obtain substantially the same result. In this sense it is therefore contemplated that an equivalent substitution of two or more elements may be made for any one of the elements in the invention and its various embodiments or that a single element may be substituted for two or more elements in a claim.

Changes from the claimed subject matter as viewed by a person with ordinary skill in the art, now known or later devised, are expressly contemplated as being equivalents within the scope of the invention and its various embodiments. Therefore, obvious substitutions now or later known to one with ordinary skill in the art are defined to be within the scope of the defined elements. The invention and its various embodiments are thus to be understood to include what is specifically illustrated and described above, what is conceptually equivalent, what can be obviously substituted, and also what essentially incorporates the essential idea of the invention.

While the invention has been described with reference to at least one preferred embodiment, it is to be clearly understood by those skilled in the art that the invention is not limited thereto. Rather, the scope of the invention is to be interpreted only in conjunction with the appended claims and it is made clear, here, that the inventor(s) believe that the claimed subject matter is the invention.

What is claimed is:

1. A thin film device comprising: a well formed in a dielectric thin film; the well covered by a further thin film layer enabled for enhancing <002> crystal growth of a deposited piezoelectric thin film layer grown on the further thin film layer; the piezoelectric thin film layer sandwiched between a bottom and a top electrode layers defining an active region therebetween, the active region adjacent the well.

2. The device of claim 1 wherein the dielectric thin film is silicon oxide.

3. The device of claim 2 wherein the silicon oxide is thermally grown.

4. The device of claim 1 wherein the piezoelectric thin film layer is formed by sputtering.

5. The device of claim 1 wherein the well is filled with a sacrificial material, the sacrificial material and the dielectric thin film forming a common surface and wherein the dielectric thin film and the sacrificial material are patterned using a single common mask.

6. The device of claim 4 wherein the sacrificial material is copper.

7. The device of claim 5 wherein the sacrificial material is patterned by removal of a photoresist layer thereunder.

8. The device of claim 1 wherein the electrode layers are formed of at least one of: molybdenum, tungsten, platinum, tantalum and aluminum.

9. The device of claim 1 wherein the further thin film layer is at least one of: Al₂O₃, SiON, calcium fluoride, and tantalum pentoxide.

10. The device of claim 1 wherein contact portions of the electrode layers are covered by a gold layer for electrical contact with a contact material.

11. The device of claim 1 wherein ground shields are placed around the contact portions of the electrode layers.

12. The device of claim 1 wherein the piezoelectric film is at least one of: AlN, ZnO and Li-niobate.

13. The device of claim 11 wherein the electrode metal layers spaced apart from the bottom and top ground shields.

14. A method for fabricating a thin film device comprising the steps of: forming a well formed in a dielectric thin film; covering the well with a further thin film layer enabled for enhancing <002> crystal growth of a deposited piezoelectric thin film layer; growing the piezoelectric thin film layer on the further thin film layer; sandwiching the piezoelectric thin film layer between a bottom and a top electrode layers defining an active region therebetween; and placing the active region adjacent the well.

15. The method of claim 14 further comprising the step of: forming the piezoelectric thin film layer by sputtering.

16. The method of claim 14 further comprising the steps of: filling the well with a sacrificial material; and establishing a common surface for the sacrificial material and the dielectric thin film.

17. The method of claim 14 further comprising the step of: patterning the sacrificial material by removal of a photoresist layer thereunder.

18. The method of claim 14 further comprising the step of: covering contact portions of the electrode layers with a gold layer for electrical contact with a contact material.

19. The method of claim 14 further comprising the step of: placing ground shields around contact portions of the electrode layers.

20. The method of claim 14 further comprising the step of: spacing the electrode metal layers spaced apart from the bottom and top ground shields.

21. The method of claim 14 further comprising the steps of: patterning and etching the piezoelectric layer thereby exposing the contact areas of the bottom electrode and the sacrificial material in the well, and removing the piezoelectric film from the contact areas and the sacrificial material from the well.
